(19) United States
(12) Patent Application Publication
(10) Pub. No.: US 2006/0038249 A1
(43) Pub. Date: Feb. 23, 2006

(54) Semiconductor light-receiving device and UV sensor apparatus

(75) Inventor: Junichiro Koyama, Kitakatsuragi-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/184,858

(22) Filed: Jul. 20, 2005

(30) Foreign Application Priority Data
Aug. 23, 2004 (JP) 2004-241879(P)

(51) Int. Cl. H01L 27/14

(52) U.S. Cl. 257/431

(57) ABSTRACT

A semiconductor light-receiving device and a UV sensor apparatus that have high photoelectric conversion efficiency even for short-wavelength radiation are provided. The semiconductor light-receiving device includes a cathode layer and anode layers formed at a surface of the cathode layer. A part of the cathode layer that is located between a pn junction between the cathode layer and one anode layer and a pn junction between the cathode layer and the other anode layer is a light-receiving region.

This nonprovisional application is based on Japanese Patent Application No. 2004-241879 filed with the Japan Patent Office on Aug. 23, 2004, the entire contents of which are hereby incorporated by reference.

### BACKGROUND OF THE INVENTION

1. Field of the Invention

The present invention relates to a semiconductor light-receiving device and an ultraviolet radiation (hereinafter UV) sensor apparatus. In particular, the invention relates to a semiconductor light-receiving device used for such an apparatus as UV sensor.

2. Description of the Background Art

Solar radiation includes such short-wavelength radiation as UV radiation. Therefore, if we spend time outdoors on a fine day in any season in which a large amount of UV radiation reaches the earth's surface, we are accordingly exposed to a large amount of UV radiation. Further, the destruction of the ozone layer is causing increases of the amount of UV radiation in those regions close to the North Pole and the South Pole. It is known that excessive exposure to UV radiation adversely affects the health, for example, causes skin cancer. Accordingly, it is a recent trend to measure the amount of UV radiation for controlling the amount of UV radiation to which we are exposed. A necessity to have a low-cost and easily-available UV sensor thus arises.

An example of the semiconductor light-receiving device receiving such short-wavelength radiation as UV radiation is the one using a group III-V compound semiconductor that is, however, costly. Therefore, most semiconductor light-receiving devices use silicon-based materials.

FIG. 5 is a schematic cross-sectional view showing a structure of a generally used silicon photodiode. Referring to FIG. 5, an n-type silicon substrate is used as a cathode layer 1. From a surface of this cathode layer 1, such p-type impurities as boron are diffused to form an anode layer 2. The region where anode layer 2 is formed is a light-receiving region 3. A semiconductor light-receiving device of this type is disclosed for example in Japanese Patent Laying-Open No. 2000-299487.

When light rays are incident on and penetrates the silicon substrate, the light energy is absorbed by the silicon to generate photo carriers and accordingly photocurrent flows. The depth in the silicon substrate to which the light rays penetrate varies depending on the wavelength of the incident light. Light with shorter wavelengths is absorbed at a depth closer to the surface of the silicon substrate. The above-described photo carriers include those carriers that disappear due to recombination before reaching a pn junction and thus do not contribute to the photocurrent. In order to prevent this, a light-receiving device adapted to receive such short-wavelength radiation as UV radiation has a pn junction formed at a smaller depth from the surface of the silicon substrate, generally at a depth of 1 μm or less.

As to the range of wavelengths of UV radiation, UV radiation ranging in wavelength approximately from 320 nm to 380 nm is called UVA radiation and UV radiation approximately from 290 nm to 320 nm is called UVB radiation. UVB radiation is particularly harmful to the health. If this UVB radiation is incident on and penetrates the silicon substrate, at least 90% of the light energy is absorbed in the region from the surface to a depth of approximately 50 nm. Photodiodes that are produced through a commonly used silicon photodiode process have a junction depth of approximately 300 nm to 700 nm at the minimum.

Therefore, when UVB radiation is incident on and penetrates the photodiode in FIG. 5, light energy absorbed by anode layer 2 causes generation of electron-hole pairs, electrons 7 of the pairs are drawn toward and reach the pn junction under the influence of an internal electric field 8 that is generated due to a concentration gradient, and thus photocurrent flows.

The surface of anode layer 2 is generally coated with a silicon oxide film 5. At and around the interface therebetween, a number of interface states 9 are present and many recombinations take place via interface states 9. In the region from the surface to the depth of 50 nm of the silicon substrate, there is almost no concentration gradient of anode layer 2. Thus, only a few internal electric fields 8 are generated in this region. Most of photo carriers generated in the region from the surface to the depth of 50 nm are accordingly recombined at interface states 9 to disappear. In other words, only small photocurrent flows and the photoelectric conversion efficiency is considerably low.

### SUMMARY OF THE INVENTION

An object of the present invention is therefore to provide a semiconductor light-receiving device and a UV sensor apparatus that have high photoelectric conversion efficiency even for short-wavelength radiation.

A semiconductor light-receiving device according to the present invention includes a first-conductivity-type semiconductor layer and a pair of second-conductivity-type semiconductor layers formed at a surface of the first-conductivity-type semiconductor layer, and the first-conductivity-type semiconductor layer has a part that is a light-receiving region located between a pn junction between the first-conductivity-type semiconductor layer and one of the second-conductivity-type semiconductor layers and a pn junction between the first-conductivity-type semiconductor layer and the other of the second-conductivity-type semiconductor layers.

The semiconductor light-receiving device of the present invention has the light-receiving region located between the pn junctions between the first-conductivity-type semiconductor layer and the second-conductivity-type semiconductor layers. Therefore, a sufficient reverse voltage can be applied to the pn junctions to allow depletion layers to contact each other in the light-receiving region. Here, the depletion layers extend respectively from the pn junctions located on respective lateral sides of the light-receiving region. Within the depletion layers, a large electric field is generated from the contact portion between the depletion layers toward each pn junction. If the first-conductivity-type semiconductor layer is an n-type layer, the electric field is a positive electric field. If the first-conductivity-type semiconductor layer is a p-type layer, the electric field is a negative electric field. When short-wavelength radiation is incident on and penetrates the light-receiving region, electron-hole pairs are generated in the vicinity of the surface. In the case where the first-conductivity-type semiconductor layer is the n-type layer, holes are drawn by the large positive electric field in the depletion layers. In the case where the first-conductivity-type semiconductor layer is the p-type layer, electrons are drawn by the large negative electric field in the depletion layers. Then, the holes or electrons are directed to and reach the pn junctions. The amount of carriers that disappear due to interface states is thus considerably reduced and the conversion efficiency is improved.

Regarding the semiconductor light-receiving device, at the surface of the first-conductivity-type semiconductor layer, preferably the second-conductivity-type semiconductor layers are formed to enclose the light-receiving region.

Thus, the structure having the light-receiving region located between the pn junctions between the first-conductivity-type semiconductor layer and the second-conductivity-type semiconductor layers can be achieved.

Regarding the semiconductor light-receiving device, at the surface of the first-conductivity-type semiconductor layer, preferably the second-conductivity-type semiconductor layers are provided in the shape of a lattice.

Thus, a plurality of light-receiving regions can be arranged densely.

Regarding the semiconductor light-receiving device, preferably an interconnection electrically connected to the second-conductivity-type semiconductor layers is provided to cover a surface of the second-conductivity-type semiconductor layers.

Thus, the series resistance can be reduced when current flows in the second-conductivity-type semiconductor layers.

Regarding the semiconductor light-receiving device, preferably a silicon substrate is used as the first-conductivity-type semiconductor layer and a pair of the second-conductivity-type semiconductor layers is formed at a surface of the silicon substrate.

The silicon substrate can be used to produce the semiconductor light-receiving device at a lower cost than that required when a group III-V compound semiconductor is used.

Regarding the semiconductor light-receiving device, preferably a reverse voltage is applied to each of the pn junctions, located respectively on lateral sides of the light-receiving region, to the degree that at least allows depletion layers extending respectively from the pn junctions to contact each other in the light-receiving region.

Thus, a large electric field as discussed above can be generated in the depletion layers. Then, when short-wavelength radiation is incident on and penetrates the light-receiving region, holes generated in the vicinity of the surface are drawn by the large electric field in the depletion layers and directed to the pn junctions. The amount of carriers that disappear due to the interface states can considerably be reduced and the photoelectric conversion efficiency is improved.

Regarding the semiconductor light-receiving device, preferably a high-resistivity silicon substrate is used as the silicon substrate.

Regarding the semiconductor light-receiving device, preferably the silicon substrate is a high-resistivity silicon substrate having a resistivity of at least 1000 Ωscm, the light-receiving region has a width of at least 10 μm and at most 300 μm and a reverse voltage of at least 1 V and at most 20 V is applied to the pn junctions.

Thus, the depletion layers extending respectively from the pn junctions on respective lateral sides of the light-receiving region can be brought into contact with each other.

A UV sensor apparatus of the present invention uses the semiconductor light-receiving device as discussed above.

In this way, a UV sensor can easily be obtained at low cost.

As heretofore discussed, according to the present invention, a semiconductor light-receiving device with high photoelectric conversion efficiency even for short-wavelength radiation can be obtained and, the semiconductor light-receiving device can be used to easily obtain a UV sensor at low cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a structure of a semiconductor light-receiving device according to an embodiment of the present invention.

FIG. 2 is a plan view similar to FIG. 1 except that an anode layer in FIG. 1 is not shown.

FIG. 3 is a schematic cross-sectional view along line III-III in FIG. 1.

FIG. 4 is a schematic cross-sectional view showing a state in which a reverse voltage is applied to pn junctions of the semiconductor light-receiving device shown in FIG. 1.

FIG. 5 is a schematic cross-sectional view showing a structure of a conventional photodiode.

### DESCRIPTION OF THE PREFERRED EMBODIMENTS

An embodiment of the present invention is hereinafter described in conjunction with the drawings.

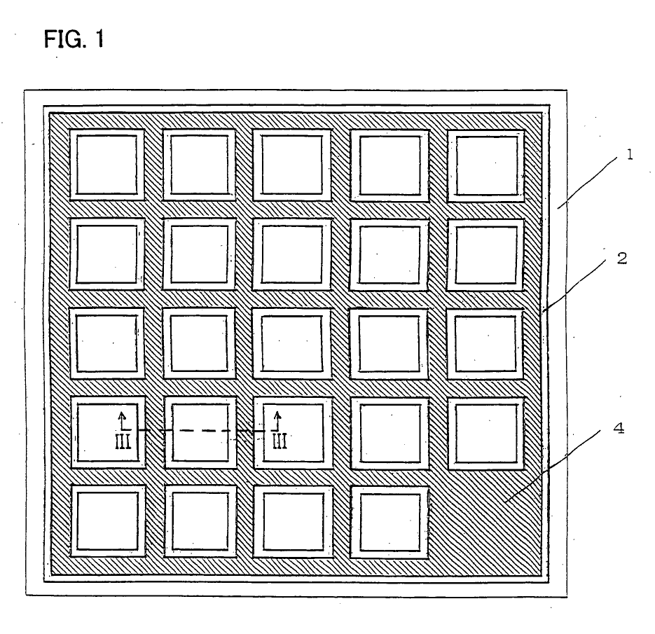

Referring to FIGS. 1, 2 and 3, a semiconductor light-receiving device in this embodiment includes a first-conductivity-type semiconductor layer 1 and a pair of second-conductivity-type semiconductor layers 2 formed at a surface of first-conductivity-type semiconductor layer 1. A feature of the semiconductor light-receiving device is that a part of first-conductivity-type semiconductor layer 1 that is located between a pn junction between first-conductivity-type semiconductor layer 1 and one second-conductivity-type semiconductor layer 2 and a pn junction between first-conductivity-type semiconductor layer 1 and the other second-conductivity-type semiconductor layer 2 is a light-receiving region 3.

First-conductivity-type semiconductor layer 1 is a cathode layer for example. As cathode layer 1, an n-type silicon substrate for example is used. Second-conductivity type semiconductor layer 2 is for example a p-type anode layer. P-type anode layer 2 is for example formed at the surface of cathode layer 1 by diffusion of such p-type impurities as boron from the surface of cathode layer 1. Light-receiving region 3 is a region of cathode layer 1 that is located in the cross section between the pn junction between one of paired anode layers 2 and cathode layer 1 and the pn junction between the other anode layer of paired anode layers 2 and cathode layer 1.

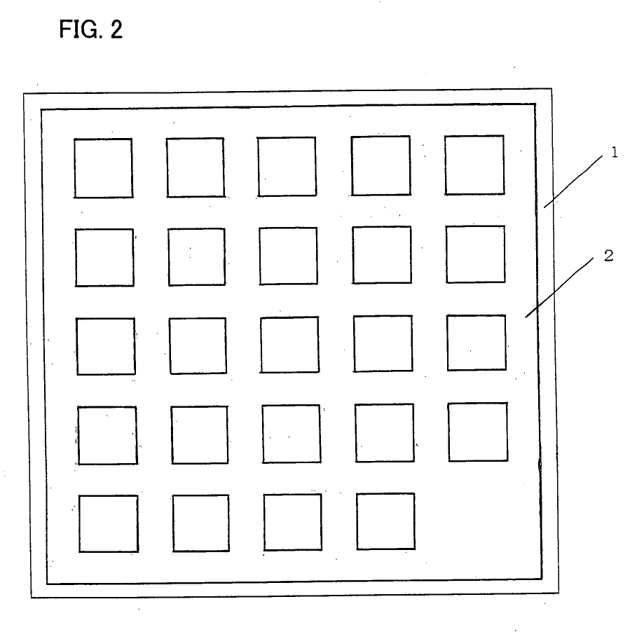

Preferably, anode layers 2 are formed as shown in FIG. 2 to enclose light-receiving region 3 at the surface of silicon substrate. Still preferably, anode layers 2 are provided as shown in FIG. 2 in the shape of a lattice at the surface of silicon substrate. In this case, at the surface of the silicon substrate, regions of cathode layer 1 that are located between the strip portions of the lattice of anode layers 2 are light-receiving regions 3.

On the surface of the silicon substrate, a silicon oxide film 5 is formed. This silicon oxide film 5 is partially removed to form holes in silicon oxide film 5 that reach a part of the surface of anode layer 2. For a plurality of electrical connections with anode layer 2 through such holes, an anode electrode 4 of a metal interconnection for example is formed. Anode electrode 4 is formed in the shape of a lattice to cover the surface of anode layer 2, in order to reduce series resistance when current flows. Further, a cathode electrode 6 is formed on the rear surface of the silicon substrate.

The above-described components are formed through a common photodiode process.

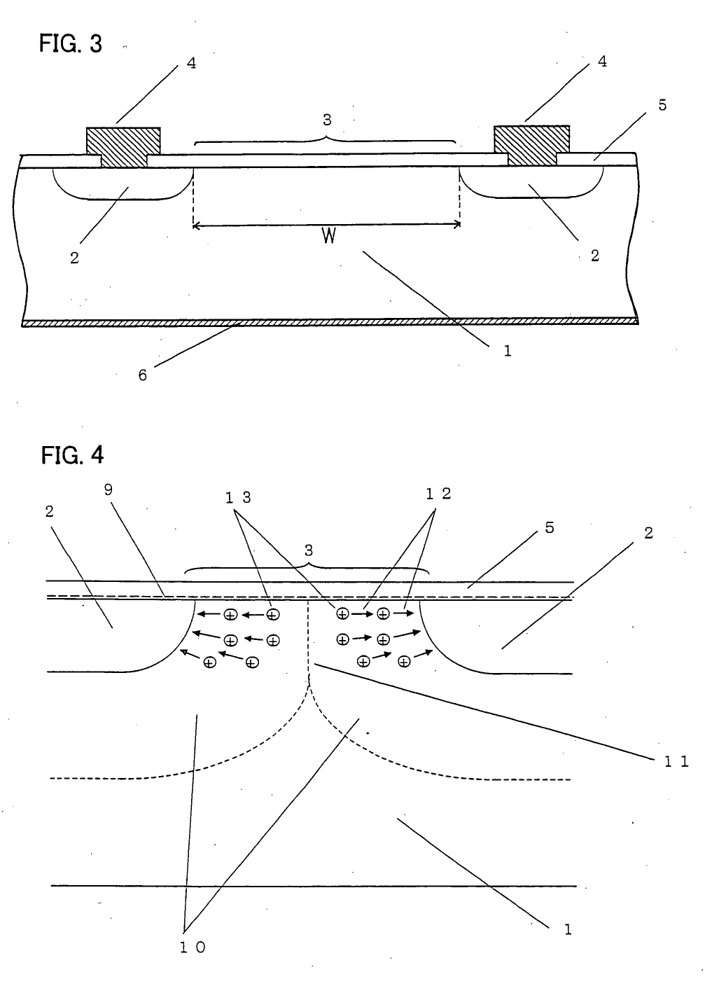

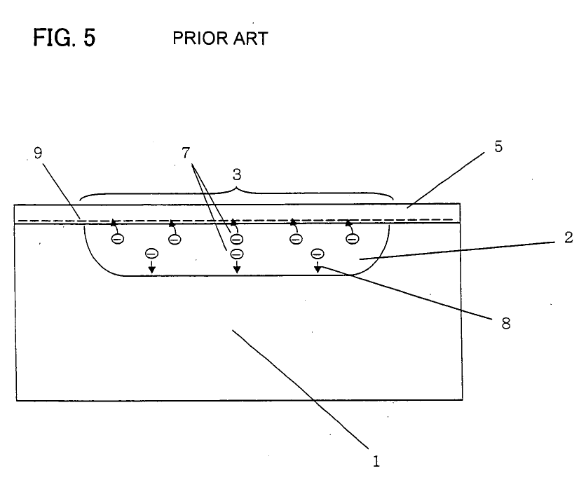

Referring to FIG. 4, a reverse voltage is applied to each of the pn junctions to the degree that at least causes contact between depletion layers 10 extending respectively from the pn junctions on respective lateral sides of light-receiving region 3. The silicon substrate is for example a high-resistivity silicon substrate having its resistivity of at least 1000 Ωcm, light-receiving region 3 has its width W (FIG. 3) for example of at least 10 μm and at most 300 μm, and the reverse voltage applied to the pn junctions is for example at least 1 V and at most 20 V. Under the above-described conditions, depletion layers 10 that extend respectively from the pn junctions on respective lateral sides of light-receiving region 3 can be brought into contact with each other in light-receiving region 3.

According to the present embodiment, with reference to FIG. 4, since light-receiving region 3 is located between the pn junctions between cathode layer 1 and respective anode layers 2, a sufficient reverse voltage can be applied to the pn junctions to allow depletion layers 10 extending respectively from the pn junctions on the lateral sides of the light-receiving region to contact each other in light-receiving region 3. In depletion layers 10, a large electric field 12 is generated from a contact portion 11 between depletion layers 10 toward each of the pn junctions. Thus, when such short-wavelength radiation as UV radiation is incident on and penetrates light-receiving region 3, electron-hole pairs are generated in the vicinity of the surface and holes 13 are drawn by large electric field 12 in depletion layers 10 and directed to the pn junctions. Accordingly, the amount of carriers that disappear due to interface states 9 is remarkably reduced and the conversion efficiency is improved.

The semiconductor light-receiving device in the present embodiment is particularly appropriate for reception of UVA radiation with the wavelength ranging from 320 nm to 380 nm, UVB radiation with the wavelength ranging from 290 nm to 320 nm and any light radiation with shorter wavelengths, and may be used for a short-wavelength radiation sensor like UV sensor.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor light-receiving device comprising:
a first-conductivity-type semiconductor layer; and
a pair of second-conductivity-type semiconductor layers formed at a surface of said first-conductivity-type semiconductor layer, wherein
said first-conductivity-type semiconductor layer has a part that is a light-receiving region located between a pn junction between said first-conductivity-type semiconductor layer and one of said second-conductivity-type semiconductor layers and a pn junction between said first-conductivity-type semiconductor layer and the other of said second-conductivity-type semiconductor layers.

2. The semiconductor light-receiving device according to claim 1, wherein
at the surface of said first-conductivity-type semiconductor layer, said second-conductivity-type semiconductor layers are formed to enclose said light-receiving region.

3. The semiconductor light-receiving device according to claim 2, wherein
at the surface of said first-conductivity-type semiconductor layer, said second-conductivity-type semiconductor layers are provided in the shape of a lattice.

4. The semiconductor light-receiving device according to claim 1, wherein
an interconnection electrically connected to said second-conductivity-type semiconductor layers is provided to cover a surface of said second-conductivity-type semiconductor layers.

5. The semiconductor light-receiving device according to claim 1, wherein
a silicon substrate is used as said first-conductivity-type semiconductor layer and a pair of said second-conductivity-type semiconductor layers is formed at a surface of said silicon substrate.

6. The semiconductor light-receiving device according to claim 5, wherein
a reverse voltage is applied to each of said pn junctions, located respectively on lateral sides of said light-receiving region, to the degree that at least allows depletion layers extending respectively from said pn junctions to contact each other in said light-receiving region.

7. The semiconductor light-receiving device according to claim 5, wherein
a high-resistivity silicon substrate is used as said silicon substrate.

8. The semiconductor light-receiving device according to claim 5, wherein
said silicon substrate is a high-resistivity silicon substrate having a resistivity of at least 1000 Ωcm, said light-receiving region has a width of at least 10 μm and at most 300 μm and a reverse voltage of at least 1 V and at most 20 V is applied to said pn junctions.

9. A UV sensor apparatus using the semiconductor light-receiving device as recited in claim 1.
